(19) United States
(12) Patent Application Publication
(10) Pub. No.: US 2026/0084984 A1
(43) Pub. Date: Mar. 26, 2026

(54) System and Method for Thermoelectric Distillation and Electricity Generation

(71) Applicant: Bryce Harper, Dallas, TX (US)

(72) Inventor: Bryce Harper, Dallas, TX (US)

(21) Appl. No.: 19/337,493

(22) Filed: Sep. 23, 2025

Related U.S. Application Data
(60) Provisional application No. 63/697,751, filed on Sep. 23, 2024.

(51) Int. Cl. C02F 1/04; B01D 3/00; H02S 10/10; H02S 10/40; H02S 40/34; H10N 19/00

(52) U.S. Cl. CPC C02F 1/04; B01D 3/007; H02S 10/10; H02S 40/34; H10N 19/00; C02F 2201/009; C02F 2303/10; H02S 10/40

(57) ABSTRACT

A distillation and electricity generation system and method includes a first cooling section, a condenser section and a second cooling section. A first thermoelectric section includes one or more first thermoelectric modules interposed between the first cooling section and the condenser section. Each first thermoelectric module has a cold side in contact with the first cooling section and a hot side in contact with the condenser section. A second thermoelectric section includes one or more second thermoelectric modules interposed between the second cooling section and the condenser section. Each second thermoelectric module has a cold side in contact with the second cooling section and a hot side in contact with the condenser section. An electrical outlet is coupled to the first thermoelectric module(s), or the second thermoelectric module(s), or both the first and second thermoelectric modules

### CROSS-REFERENCE TO RELATED APPLICATIONS

This application claims priority to U.S. Provisional Patent Application Ser. No. 63/697,751 filed on Sep. 23, 2024, which is hereby incorporated by reference in its entirety.

### TECHNICAL FIELD OF THE INVENTION

The present invention relates in general to the field of thermoelectric systems, and more particularly, to a system and method for thermoelectric distillation and electricity generation.

### STATEMENT OF FEDERALLY FUNDED RESEARCH

Not applicable.

### BACKGROUND OF THE INVENTION

Without limiting the scope of the invention, its background is described in connection with thermoelectric distillation.

As illustrated in U.S. Pat. No. 6,893,540, prior art distillation systems use Peltier effect devices or thermoelectric modules to heat a liquid, such as water, to vapor (steam) and cool the vapor to a purified distilled liquid. These systems do not use a separate sources of cooling liquid and heat to generate electricity using the Peltier effect devices or thermoelectric modules while still producing the purified distilled liquid.

Accordingly, there is a need for a system and method for thermoelectric distillation and electricity generation.

### SUMMARY OF THE INVENTION

The thermoelectric distillation module (“TDM”) described herein is a device that functions as both a distillery and an electric generator with only heat as its input energy. The TDM purifies and removes almost all contaminants out of a given water sample while simultaneously producing an electric current which can be used to charge electronics or battery power supplies. The TDM can be portable and is usable in the wilderness as long as there is a heat source and a cool water source. The TDM can be powered by any source of heat, this includes wood fire, gas stoves or even electric stoves.

The TDM uses the natural heat differential produced during the process of distillation to energize thermoelectric harvesters. Through the implementation of this heat differential, both the distillation and energy generation processes are extremely efficient. The TDM can be implemented in portable, user-friendly consumer devices. The TDM is useful in many different scenarios, such as camping, hiking, survival gear, power and/or water outages, a location with limited access to resources, a location affected by natural or human-made disasters, etc.

In one embodiment of the present disclosure, a distillation and electricity generation system includes a first cooling section configured to receive a cooling liquid, a condenser section configured to condense steam into distilled water, a second cooling section configured to receive the cooling liquid, a first thermoelectric section, a second thermoelectric section, and an electrical outlet. The first thermoelectric section includes one or more first thermoelectric modules interposed between the first cooling section and the condenser section, wherein each first thermoelectric module has a cold side in contact with the first cooling section, a hot side in contact with the condenser section, and is configured to generate electricity based on a first temperature difference between the hot side and the cold side of the first thermoelectric module. The second thermoelectric section includes one or more second thermoelectric modules interposed between the second cooling section and the condenser section, wherein each second thermoelectric module has a cold side in contact with the second cooling section, a hot side in contact with the condenser section, and is configured to generate electricity based on a second temperature difference between the hot side and the cold side of the second thermoelectric module. The electrical outlet is coupled to the first thermoelectric module(s), or the second thermoelectric module(s), or both the first and second thermoelectric modules.

In one aspect, the one or more first thermoelectric modules include two or more first thermoelectric modules, the one or more second thermoelectric modules include two or more second thermoelectric modules, the electrical outlet includes a first electrical outlet, a second electrical outlet is coupled to at least one of the two or more first thermoelectric modules or the two or more second thermoelectric modules, and the first electrical outlet is coupled to the two or more first thermoelectric modules and the two or more second thermoelectric modules that are not coupled to the second electrical outlet. In another aspect, the first electrical outlet is configured to charge a device or battery, or to power the device, and the second electrical outlet is configured to power a pump. In another aspect, all of the first and second thermoelectric modules coupled to the second electrical outlet are connected together in series, all of the first and second thermoelectric modules coupled to the first electrical outlet are configured into one or more groups of thermoelectric modules, all of the first and second thermoelectric modules in each group of thermoelectric modules are connected together in series, and all of the groups of thermoelectric modules are connected together in parallel. In another aspect, the pump is electrically connected to the second electrical output, and the pump is configured to pump water from a water source into the first cooling section, or the second cooling section, or both the first and second cooling sections via a tube, hose or pipe. In another aspect, a vessel is configured to receive heat from a heat source, create steam from water contained within the vessel using the heat, and direct the steam into the condenser section via a tube, hose or pipe. In another aspect, a receptacle configured to receive the distilled water from the condenser section. In another aspect, a tube, hose or pipe connecting the first cooling section to the second cooling section. In another aspect, the condenser section comprises a first condenser section, one or more expansion units coupled to the first cooling section or the second cooling section, each expansion unit includes: a second condenser section, a third cooling section, a third thermoelectric section comprising one or more third thermoelectric modules interposed between the second condenser section and the first cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and a fourth thermoelectric section comprising one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module; and wherein the electrical outlet is further coupled to the third thermoelectric module(s), or the fourth thermoelectric module(s), or both the third and fourth thermoelectric modules. In another aspect, one or more solar cells or panels are coupled to the electrical outlet. In another aspect, the first cooling section, the second cooling section and the condenser section each include: a rectangular shaped body having an inlet and an outlet, wherein the rectangular shaped body is made of a thermally conductive material, and one or more passageways disposed within the rectangular shaped body and connected to the inlet to the outlet. In another aspect, a tube, hose or pipe connects the outlet of the first cooling section to the inlet of the second cooling section, or the outlet of the second cooling section to the inlet of the first cooling section. In another aspect, one or more radiator fins are attached to an exterior of the first cooling section, or the second cooling section, or both the first and second cooling sections. In another aspect, the first cooling section, the condenser section and the second cooling section comprise a primary condenser; and a secondary condenser is coupled to the primary condenser, wherein the secondary condenser comprises an additional condenser section disposed between a third cooling section and a fourth cooling section.

In another embodiment of the present disclosure, a distillation and electricity generation system includes a first cooling section configured to receive a cooling liquid, a condenser section configured to condense steam into distilled water, a second cooling section configured to receive the cooling liquid, a first thermoelectric section, a second thermoelectric section, a first electrical outlet, and a second electrical outlet. The first cooling section, the second cooling section and the condenser section each include: a rectangular shaped body having an inlet and an outlet, wherein the rectangular shaped body is made of a thermally conductive material, and one or more passageways disposed within the rectangular shaped body and connected to the inlet to the outlet. The first thermoelectric section includes two or more first thermoelectric modules interposed between the first cooling section and the condenser section, wherein each first thermoelectric module has a cold side in contact with the first cooling section, a hot side in contact with the condenser section, and is configured to generate electricity based on a first temperature difference between the hot side and the cold side of the first thermoelectric module. The second thermoelectric section includes two or more second thermoelectric modules interposed between the second cooling section and the condenser section, wherein each second thermoelectric module has a cold side in contact with the second cooling section, a hot side in contact with the condenser section, and is configured to generate electricity based on a second temperature difference between the hot side and the cold side of the second thermoelectric module. The second electrical outlet is coupled to at least one of the two or more first thermoelectric modules or the two or more second thermoelectric modules. The first electrical outlet is coupled to the two or more first thermoelectric modules and the two or more second thermoelectric modules that are not coupled to the second electrical coupled.

In one aspect, the first electrical outlet is configured to charge a device or battery, or to power the device, and the second electrical outlet is configured to power a pump. In another aspect, all of the first and second thermoelectric modules coupled to the second electrical outlet are connected together in series, all of the first and second thermoelectric modules coupled to the first electrical outlet are configured into one or more groups of thermoelectric modules, all of the first and second thermoelectric modules in each group of thermoelectric modules are connected together in series, and all of the groups of thermoelectric modules are connected together in parallel. In another aspect, the pump is electrically connected to the second electrical output, and the pump is configured to pump water from a water source into the first cooling section, or the second cooling section, or both the first and second cooling sections via a tube, hose or pipe. In another aspect, a vessel is configured to receive heat from a heat source, create steam from water contained within the vessel using the heat, and direct the steam into the condenser section via a tube, hose or pipe. In another aspect, a receptacle is configured to receive the distilled water from the condenser section. In another aspect, a tube, hose or pipe connects the outlet of the first cooling section to the inlet of the second cooling section, or the outlet of the second cooling section to the inlet of the first cooling section. In another aspect, the condenser section comprises a first condenser section, one or more expansion units coupled to the first cooling section or the second cooling section, each expansion unit includes: a second condenser section, a third cooling section, a third thermoelectric section, and a fourth thermoelectric section. The third thermoelectric section includes one or more third thermoelectric modules interposed between the second condenser section and the first cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module. The fourth thermoelectric section includes one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module. The electrical outlet is further coupled to the third thermoelectric module(s), or the fourth thermoelectric module(s), or both the third and fourth thermoelectric modules. In another aspect, one or more solar cells or panels are coupled to the electrical outlet. In another aspect, one or more radiator fins are attached to an exterior of the first cooling section, or the second cooling section, or both the first and second cooling sections. In another aspect, the first cooling section, the condenser section and the second cooling section comprise a primary condenser; and a secondary condenser is coupled to the primary condenser, wherein the secondary condenser comprises an additional condenser section disposed between a third cooling section and a fourth cooling section.

In another embodiment of the present disclosure, a method includes passing a cooling liquid through a first cooling section and a second cooling section, condensing steam into water in a condenser section, generating electricity using a first thermoelectric section and a second thermoelectric section, and providing the electricity to an electrical outlet. The first thermoelectric section includes one or more first thermoelectric modules interposed between the first cooling section and the condenser section, each first thermoelectric module has a cold side in contact with the first cooling section, a hot side in contact with the condenser section, and is configured to generate electricity based on a first temperature difference between the hot side and the cold side of the first thermoelectric module. The second thermoelectric section includes one or more second thermoelectric modules interposed between the second cooling section and the condenser section, each second thermoelectric module has a cold side in contact with the second cooling section, a hot side in contact with the condenser section, and is configured to generate electricity based on a second temperature difference between the hot side and the cold side of the second thermoelectric module. The electrical outlet is coupled to the first thermoelectric module(s), or the second thermoelectric module(s), or both the first and second thermoelectric modules.

In one aspect, the method further includes charging a device or battery, or powering the device connected to the electrical outlet. In another aspect, the method further includes pumping water from a water source into the first cooling section, or the second cooling section, or both the first and second cooling sections via a tube, hose or pipe. In another aspect, the method further includes a tube, hose or pipe connecting the first cooling section to the second cooling section. In another aspect, the one or more first thermoelectric modules comprise two or more first thermoelectric modules, the one or more second thermoelectric modules comprise two or more second thermoelectric modules, the electrical outlet comprises a first electrical outlet, a second electrical outlet is coupled to at least one of the two or more first thermoelectric modules or the two or more second thermoelectric modules, and the first electrical outlet is coupled to the two or more first thermoelectric modules and the two or more second thermoelectric modules that are not coupled to the second electrical outlet. In another aspect, the method further includes powering a pump connected to the second electrical outlet. In another aspect, all of the first and second thermoelectric modules coupled to the second electrical outlet are connected together in series, all of the first and second thermoelectric modules coupled to the first electrical outlet are configured into one or more groups of thermoelectric modules, all of the first and second thermoelectric modules in each group of thermoelectric modules are connected together in series, and all of the groups of thermoelectric modules are connected together in parallel. In another aspect, the method further includes producing the steam by heating a vessel containing water, and transporting the steam from the vessel to the condenser section using a tube, hose or pipe. In another aspect, the method further includes collecting the distilled water from the condenser section in a receptacle. In another aspect, the condenser section includes a first condenser section, one or more expansion units coupled to the first cooling section or the second cooling section, each expansion unit includes: a second condenser section, a third cooling section, a third thermoelectric section including one or more third thermoelectric modules interposed between the second condenser section and the cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and a fourth thermoelectric section including one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module, and wherein the electrical outlet is further coupled to the third thermoelectric module(s), or the fourth thermoelectric module(s), or both the third and fourth thermoelectric modules. In another aspect, one or more solar cells or panels are coupled to the electrical outlet. In another aspect, the first cooling section, the second cooling section and the condenser section each include a rectangular shaped body having an inlet and an outlet, wherein the rectangular shaped body is made of a thermally conductive material, and one or more passageways disposed within the rectangular shaped body and connected to the inlet to the outlet. In another aspect, a tube, hose or pipe connects the outlet of the first cooling section to the inlet of the second cooling section, or the outlet of the second cooling section to the inlet of the first cooling section. In another aspect, one or more radiator fins are attached to an exterior of the first cooling section, or the second cooling section, or both the first and second cooling sections. In another aspect, the first cooling section, the condenser section and the second cooling section comprise a primary condenser; and a secondary condenser is coupled to the primary condenser, wherein the secondary condenser comprises an additional condenser section disposed between a third cooling section and a fourth cooling section.

Note that the invention is not limited to the embodiments described herein, instead it has the applicability beyond the embodiments described herein. The brief and detailed descriptions of this disclosure are given in the following.

### BRIEF DESCRIPTION OF THE DRAWINGS

For a more complete understanding of the features and advantages of the present invention, reference is now made to the detailed description of the invention along with the accompanying figures and in which:

FIG. 1 is a diagram of a system in accordance with one embodiment of the present disclosure;

FIG. 2 is an exploded diagram of a system in accordance with one embodiment of the present disclosure;

FIG. 3 depicts an assembly of the components of a system in accordance with one embodiment of the present disclosure;

FIG. 4 depicts a photograph of a system in accordance with one embodiment of the present disclosure;

FIG. 5A depicts an internal distillation process of a system in accordance with one embodiment of the present disclosure;

FIG. 5B depicts a flow within each section of a system in accordance with one embodiment of the present disclosure;

FIG. 5C depicts a connection between the two cooling sections of a system in accordance with one embodiment of the present disclosure;

FIG. 6 depicts a flowchart of a method in accordance with one embodiment of the present disclosure;

FIG. 7 is a photograph of a system in accordance with one embodiment of the present disclosure;

FIG. 8 is a photograph of a system in accordance with one embodiment of the present disclosure; and

FIG. 9 is a diagram of a system in accordance with one embodiment of the present disclosure.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity but include the general class of which a specific example may be used for illustration. The terminology herein is used to describe specific embodiments of the invention, but their usage does not limit the invention, except as outlined in the claims.

Various methods are described below to provide an example of each claimed embodiment. They do not limit any claimed embodiment. Any claimed embodiment may cover methods that are different from those described above and below. The drawings and descriptions are for illustrative, rather than restrictive, purposes.

The thermoelectric distillation module (“TDM) described herein is a device that functions as both a distillery and an electric generator with only heat as its input energy. The TDM purifies and removes almost all contaminants out of a given water sample while simultaneously producing an electric current which can be used to charge electronics or battery power supplies. The TDM can be portable and is usable in the wilderness as long as there is a heat source and a cool water source. The TDM can be powered by any source of heat, this includes wood fire, gas stoves or even electric stoves.

The TDM uses the natural heat differential produced during the process of distillation to energize thermoelectric harvesters. Through the implementation of this heat differential, both the distillation and energy generation processes are extremely efficient. The TDM is designed to be implemented in portable, user-friendly consumer devices. The TDM is useful in many different scenarios, such as camping, hiking, survival gear, power and/or water outages, a location with limited access to resources, a location affected by natural or human-made disasters, etc.

The TDM uses the concept of thermoelectric generation and temperature difference to both produce electricity and effectively distill water. Thermoelectric generators, also called TEG's or Peltier modules or thermoelectric modules, are devices that can be operated in two modes. The first mode is when electricity passes through the thermoelectric module, one side of the module absorbs heat and the other radiates heat. Most prior art distillation systems use this first mode to create heat the liquid and produce steam or vapor. The second mode create an electric current when one side of the thermoelectric modules it is hot and the other is cold, or a heat differential exists between the two sides. The hotter the hot side and colder the cold side is, the more electricity will be produced. Distillation works on this exact same concept. The hotter the heat source is the more steam and therefore purified water is produced and the colder the condenser is the more steam is actually condensed into liquid water. The TDM takes advantage of these phenomena by creating an extreme heat differential, thus producing a radically efficient, simultaneous method of distillation and energy generation.

In general, the operation of the TDM requires three things, the boiler, the TDM module itself, and a reservoir of cool/cold liquid. Contaminated water is placed inside of the boiler. The steam line is then connected from the boiler to the TDM module. A water pump is attached to the input water cooling line and placed into the cold liquid reservoir. As the contaminated water boils and the resulting steam is channeled through the TDM module, the pump is activated and the system self regulates. The design will produce purified water and electricity for as long there is a supply of steam and a temperature difference is present within the thermoelectric modules.

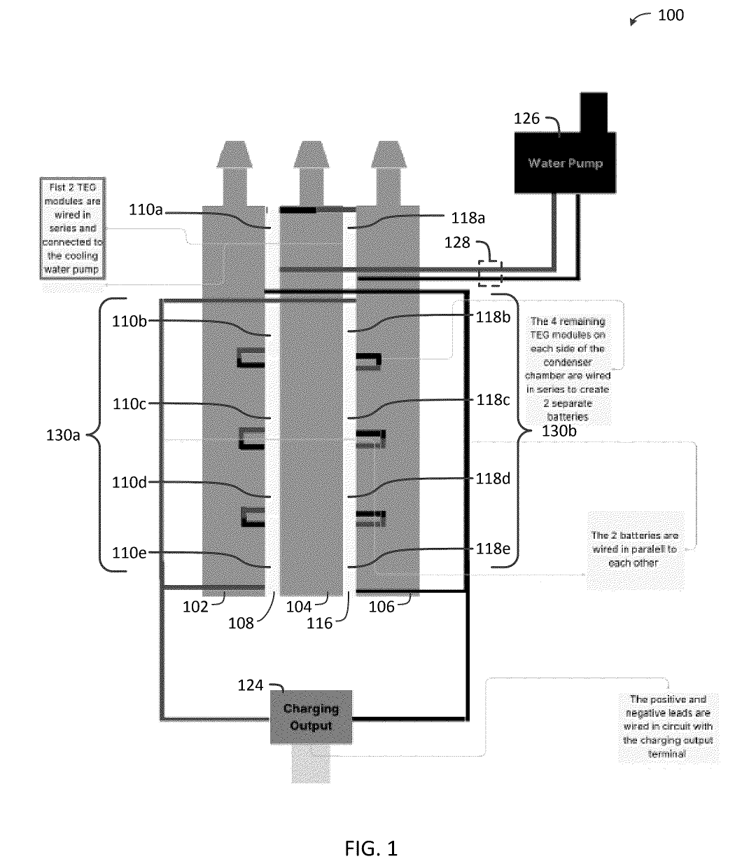

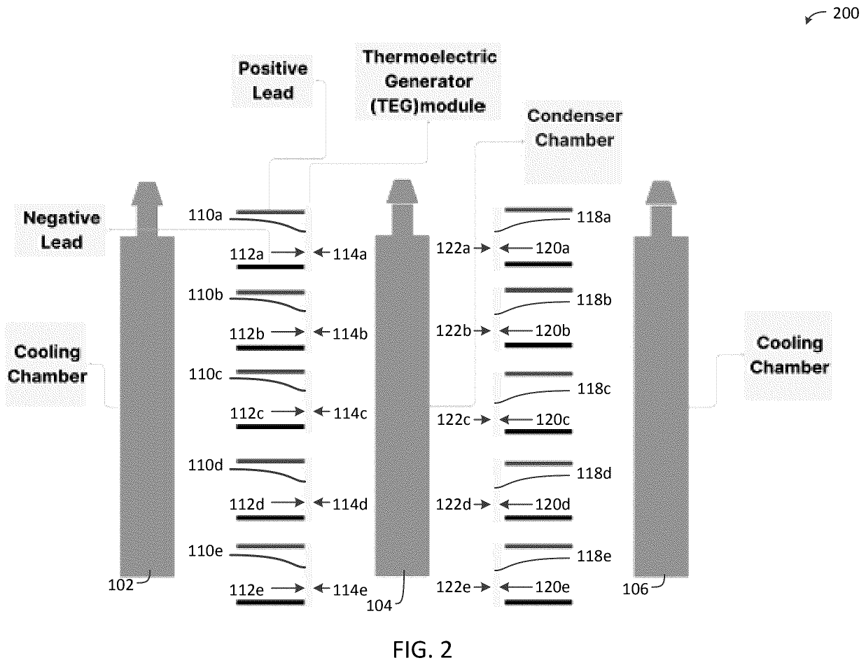

Now, referring to FIGS. 1-2, a diagram and exploded view of a system 100 in accordance with one embodiment of the present disclosure are shown. The distillation and electricity generation system 100 includes a first cooling section or chamber 102 configured to receive a cooling liquid, a condenser section or chamber 104 configured to condense steam into distilled water, and a second cooling section or chamber 106 configured to receive the cooling liquid. A first thermoelectric section 108 includes comprising one or more first thermoelectric modules 110 interposed between the first cooling section 102 and the condenser section 104. In this non-limiting example, there are five first thermoelectric modules 110a, 110b, 110c, 110d and 110e. Each first thermoelectric module 110a-110e has a cold side 112a, 112b, 112c, 112d and 112e in contact with the first cooling section 102, a hot side 114a, 114b, 114c, 114d and 114e in contact with the condenser section 104, and is configured to generate electricity based on a first temperature difference between the hot side 114a, 114b, 114c, 114d and 114e and the cold side 112a, 112b, 112c, 112d and 112e of the first thermoelectric module 110a, 110b, 110c, 110d and 110e. A second thermoelectric section 116 includes one or more second thermoelectric modules 118 interposed between the second cooling section 106 and the condenser section 104. In this non-limiting example, there are five second thermoelectric modules 118a, 118b, 118c, 118d and 118e. Each second thermoelectric module 118a, 118b, 118c, 118d and 118e has a cold side 120a, 120b, 120c, 120d and 120e in contact with the second cooling section 106, a hot side 122a, 122b, 122c, 122d and 122e in contact with the condenser section 104, and is configured to generate electricity based on a second temperature difference between the hot side 122a, 122b, 122c, 122d and 122e and the cold side 120a, 120b, 120c, 120d and 120e of the second thermoelectric module 118a, 118b, 118c, 118d and 118e. Note that more or less thermoelectric modules 110, 118 can be used. Moreover, the thermoelectric modules 110, 118 can be configured in arrays or other patterns to maximize the contact surface area of the cooling sections 102, 106 and the condenser section 104. An electrical outlet 124 (also referred to as a first electrical outlet) is coupled to the first thermoelectric module(s) 110, or the second thermoelectric module(s) 118, or both the first and second thermoelectric modules 110, 118. The electrical outlet 124 is configured to charge a device or battery, or to power the device.

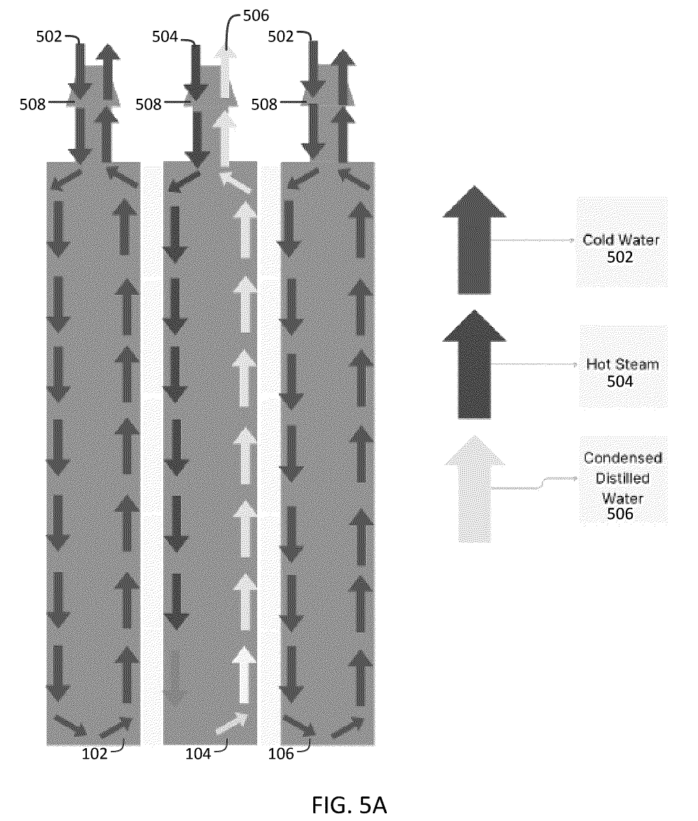

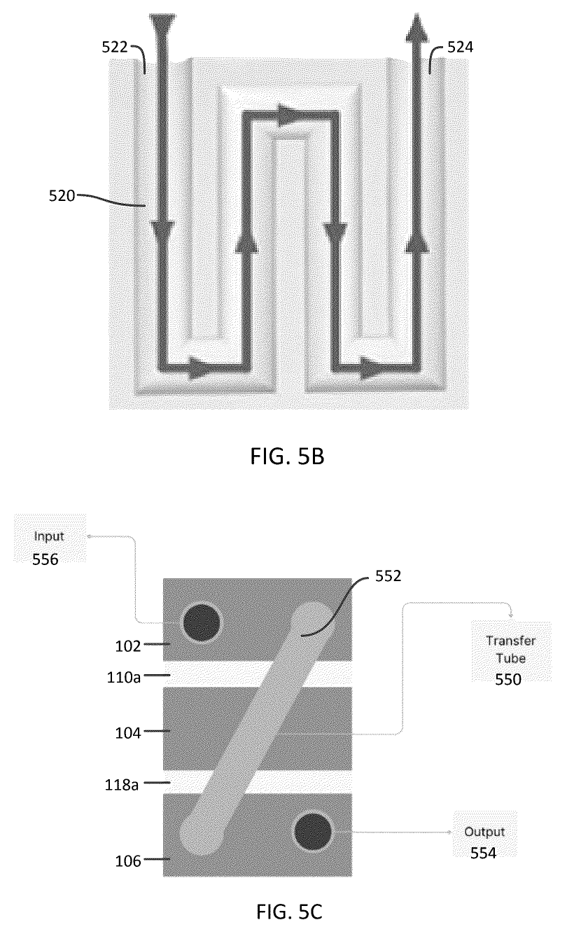

A pump 126 can be coupled to at least one of the two or more first thermoelectric modules 110 or the two or more second thermoelectric modules 118. The pump 126 is configured to pump water from a water source into the first cooling section 102, or the second cooling section 106, or both the first and second cooling sections 102, 106 via a tube, hose or pipe. As shown in FIG. 5C, a tube, hose or pipe can connect the first cooling section 102 to the second cooling section 106. Alternatively, the pump 126 can pump water into both the first and second cooling sections 102, 106 using a Y-connector or diversion device.

In the example of FIGS. 1 and 2, the pump is coupled to one of the first thermoelectric modules 110a and one of the second thermoelectric modules 118a, which are connected together in series. In other embodiments, the first thermoelectric module 110a and the second thermoelectric modules 118a can be coupled to a second electrical outlet 128, to which the pump 126 can be connected. In other embodiments, the pump 126 can be powered from an external source. The first electrical outlet 124 is coupled to the two or more first thermoelectric modules 110 and the two or more second thermoelectric modules 118 that are not coupled to the second electrical outlet 128. In this example, all of the first and second thermoelectric modules 110b, 110c, 110d, 110e, 118b, 118c, 118d, 118e coupled to the first electrical outlet 124 are configured into one or more groups of thermoelectric modules 130a and 130b, all of the first and second thermoelectric modules in each group of thermoelectric modules 130a, 130b are connected together in series, and all of the groups of thermoelectric modules 130a, 130b are connected together in parallel. Group of thermoelectric modules 130a contains thermoelectric modules 110b, 110c, 110d, 110e connected in series. Group of thermoelectric modules 130b contains thermoelectric modules 118b, 118c, 118d, 118e connected in series. Other connection configurations can be used. In addition, the system 100 may include a controller, display, switches/buttons, and/or indicator lights to control and display information of the system 100.

As stated above, the first two thermoelectric modules 110a and 118a are wired together in series and connected to the external water pump 126. This pump 126 will self-activate when the system is running and will pump cool water into the cooling sections or chambers 102 and 106. The remaining eight thermoelectric modules 110b-e and 118b-e are split into two groups of four. The four thermoelectric modules are wired in series, creating two separate batteries. There are now two sets of four thermoelectric modules wired in series. The two batteries are then wired together in parallel. The positive and negative leads from the thermoelectric modules are wired to the electrical outlet 124. The electrical outlet 124 is now able to charge and power electronic devices.

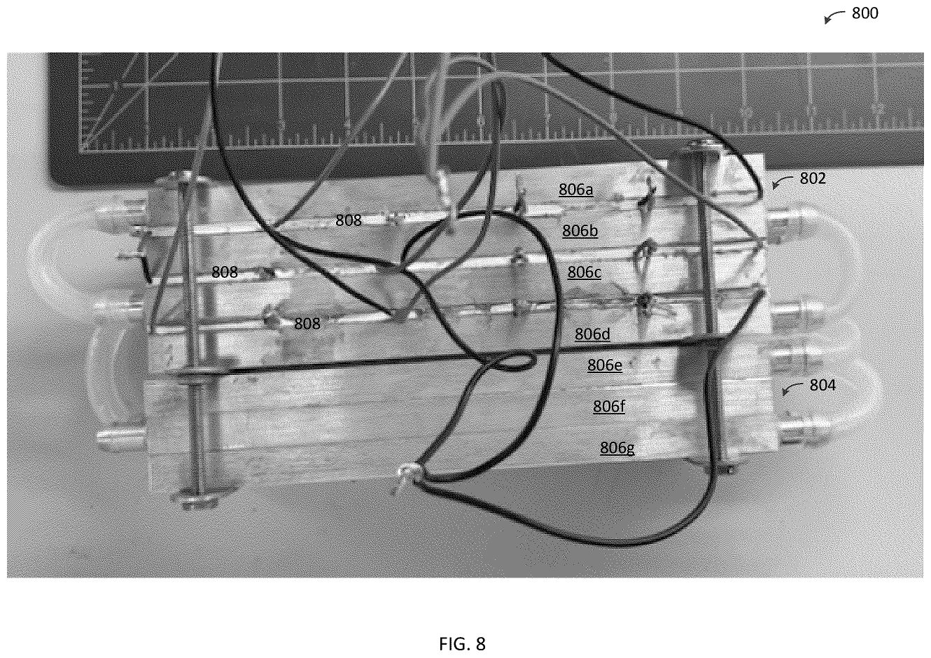

In some embodiments, the first and second cooling sections 102, 106 and the condenser section 104 are placed within a housing to protect the sections 102, 104, 106, electrical wires and connections, and provide a mounting surface for the first and second electrical outlets 124, 128. The system 100 may also be provided in a kit that includes the pump 126, tubes, hoses or pipes (described later) and/or a vessel or boiler (described later). The vessel or boiler is configured to receive heat from a heat source, create steam from water contained within the vessel using the heat, and direct the steam into the condenser section 104 via a tube, hose or pipe. Any type of receptacle can be used to receive or collect the distilled water from the condenser section 102. In some embodiments, the system 100 may include one or more solar cells or panels coupled to the first or second electrical outlets 124, 128. In some embodiments, the system 100 may include one or more radiator fins attached to an exterior of the first cooling section 102, the second cooling section 106, or both the first and second cooling sections 102, 106. In some embodiments, the first cooling section, the condenser section and the second cooling section comprise a primary condenser; and a secondary condenser is coupled to the primary condenser, wherein the secondary condenser comprises an additional condenser section disposed between a third cooling section and a fourth cooling section (see FIG. 8).

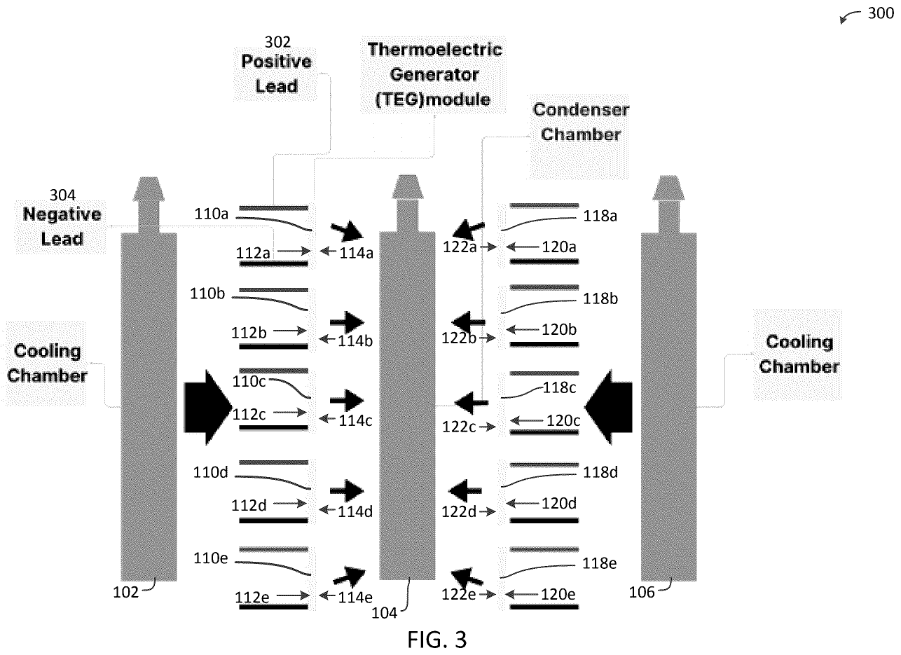

Referring now to FIG. 3, an assembly process of the components of a system in accordance with one embodiment of the present disclosure is shown. As previously stated, the cold sides 112a-e, 120a-e of the thermoelectric modules or TEG generators 110a-e, 118a-e are faced towards the two cooling sections or chambers 120, 106 on their respective ends of the module. The hot sides 114a-e, 122a-e of the thermoelectric modules or TEG generators 110a-e, 118a-e are faced towards the single condenser section or chamber 104 in the middle. Each thermoelectric module or TEG generator 110a-e, 118a-e has a positive lead 302 and a negative lead 304. The thermoelectric modules or TEG generators 110a-e, 118a-e can be attached to the first and second cooling sections or chamber 102, 106 and the condenser section or chamber 104 using an adhesive or other suitable means. For example, the components could be held in place by one or more band(s) surrounding the system. In some embodiments, the components can be removeable or configured in modules such that additional sections can be easily added.

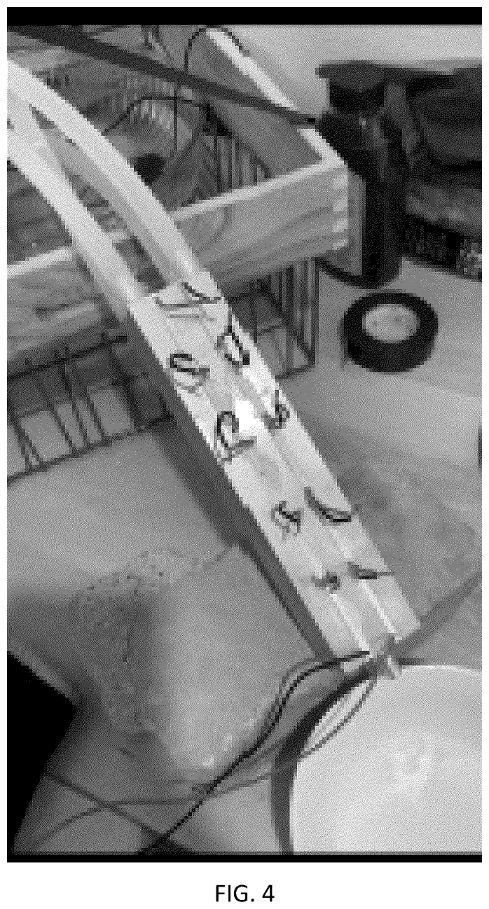

Now referring to FIG. 4, a photo of the basic design for the Standard TDM Model described above in reference to FIGS. 1-3. The Standard TDM Model includes ten TEG Peltier modules sandwiched between three aluminum liquid heat sinks. The hot sides of the TEG's are faced towards the middle heat sink while the cold sides are faced towards the two outer heat sinks. Two of the TEG modules are wired in series and connected in circuit to the water pump. The remaining eight TEG modules are wired together in series. The TEG modules powering the pump are independent of the remaining modules and are only designed to power the pump, they do not contribute to the main power output. The middle heatsink acts as both the steam reservoir and the condenser, this is where the steam from the boiler will be channeled. The two outer heatsinks act as coolers for the condenser, this is where the water pump will be connected and placed into the cold water reservoir. As cold water is pumped through the outer heat sinks, it creates the temperature difference needed to condense the steam back into water and energize the TEG modules. Multiple modules can be wired together for different product models to create even more power generation and distillation production. This standard module design generates a charging power of approximately 2.5 watts and produces approximately 1 liter of distilled water per hour.

The system 100 of FIGS. 1-4 can be expanded using expansion units as shown in FIG. 7. In such a case, the condenser section 104 is referred to as the first condenser section 104. One or more expansion units are coupled to the first cooling section 102 or the second cooling section 106. Each expansion unit includes a second condenser section, a third cooling section, a third thermoelectric section, and a fourth thermoelectric section. The third thermoelectric section includes one or more third thermoelectric modules interposed between the second condenser section and the first cooling section 102 or the second cooling section 106. Each third thermoelectric module has a cold side in contact with the first cooling section 102 or the second cooling section 106, a hot side in contact with the second condenser section, and is configured to generate electricity based on a third temperature difference between the hot side and the cold side of the third thermoelectric module. The fourth thermoelectric section includes one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module. The electrical outlet 124 is further coupled to the third thermoelectric module(s), or the fourth thermoelectric module(s), or both the third and fourth thermoelectric modules.

Referring now to FIG. 5A, an internal distillation process of the system in accordance with one embodiment of the present disclosure is shown. As previously stated, the operation of the TDM requires three things, the boiler, the TDM module itself, and a reservoir of cool/cold water. Contaminated water is placed inside of the vessel or boiler. A steam line is then connected from the boiler to the TDM module. A water pump is attached to the input water cooling line and placed into the cold water reservoir. The user of the TDM can utilize an independent cold water reservoir such as a bowl or bucket, or they can place the water pump directly into a natural water source, such as a lake, river, ocean etc. The water used for the cooling process can be of any quality, including contaminated or salt water. As the contaminated water placed in the vessel or boiler comes to a boil and the resulting steam is channeled through the TDM module, the pump is activated and the system self regulates. The design will produce purified water and electricity for as long there is a supply of steam and a temperature difference present within the module.

Cold water 502 (dark blue arrows) is pumped through the two outer cooling sections or chambers 102, 106. At the same time, steam 504 (red arrows) flows through the input of the condenser section or chamber 104. The steam 504 heats up the condenser section or chamber 104, creating the temperature difference between itself and the cooling sections or chambers 102, 106 needed to activate the system. As the cooling sections or chambers 102, 106 fight to lower the temperature of the condenser chamber 104, the steam 504 is cooled and recondensed into distilled water 506 (light blue arrows). The distilled water 506 is then collected via the condenser section or chamber's 104 output terminal while the cooling water 502 is expelled out of the cooling section or chamber's 102, 106 output terminal and returned back into whatever cold water reservoir is being used. The cooling sections 102, 106 and the condenser section 104 each have two terminals 508, one input terminal and one output terminal. In this example, the cooling sections 102, 106 and the condenser section 104 are rectangular shaped bodies. Note that other shapes can be used. The cooling sections 102, 106 and the condenser section 104 are preferably made of a thermally conductive material, such as materials used in heat sinks.

Now referring to FIG. 5B, a flow within each section of the system in accordance with one embodiment of the present disclosure is shown. The cooling sections or chambers 102, 106 and the condenser section or chamber 104 each have one or more passageways 520 disposed within the rectangular shaped body and connected to the inlet 522 to the outlet 524. The one or more passageways 520 are typically in a serpentine pattern, but other patterns can be used. For the two cooling sections or chambers 102, 106, the input 522 would accept cold water from a reservoir while the output 524 would expel the cool, now slightly warmer water back into the reservoir to be cooled and cycled through the system again. For the condenser section or chamber 104, the input 522 would accept steam from the boiler while the output 524 would expel the resulting distilled water, ready to be collected. As shown in FIG. 5C, a tube, hose or pipe 550 connected between the outlet 552 of the first cooling section or chamber 102 to the inlet 554 of the second cooling section or chamber 106. Alternatively, the tube, hose or pipe 550 can connect the outlet 554 of the second cooling section or chamber 106 to the inlet 556 of the first cooling section or chamber 102. This allows the water being expelled by the one of the cooling sections or chambers to be channeled into and cycled through the other cooling section or chamber. This method allows cold water to cycle through both cooling chambers by using only one input terminal and one output terminal. The water is then expelled from the system through the lower cooling chambers output terminal. This method of connecting output terminals with input terminals can be applied to both the cooling chambers and the condenser chamber(s), though high temperature silicone tubing, or an equivalent, is required for use on a condenser chamber 104. This allows the TDM to be scaled up exponentially while still only using one input and output terminal by simply adding more cooling/condensing chambers and connecting the required terminals together.

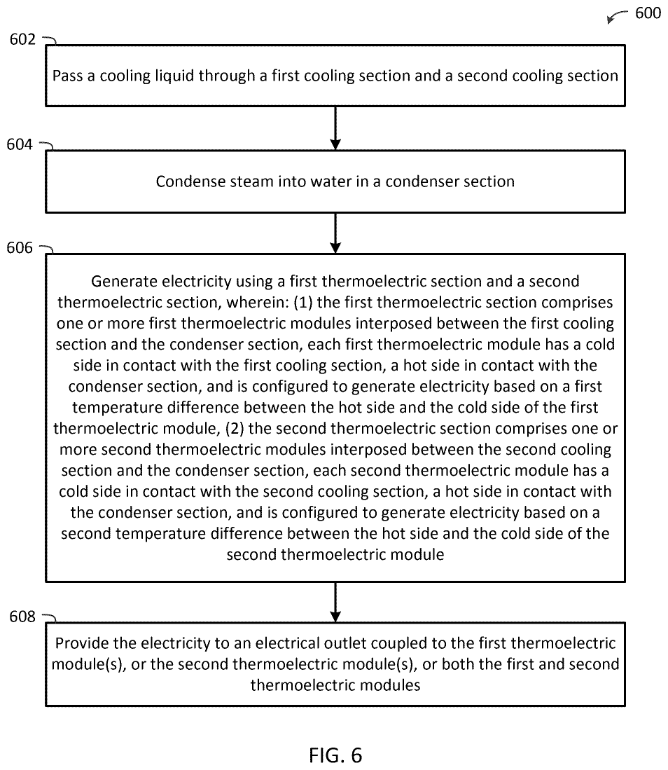

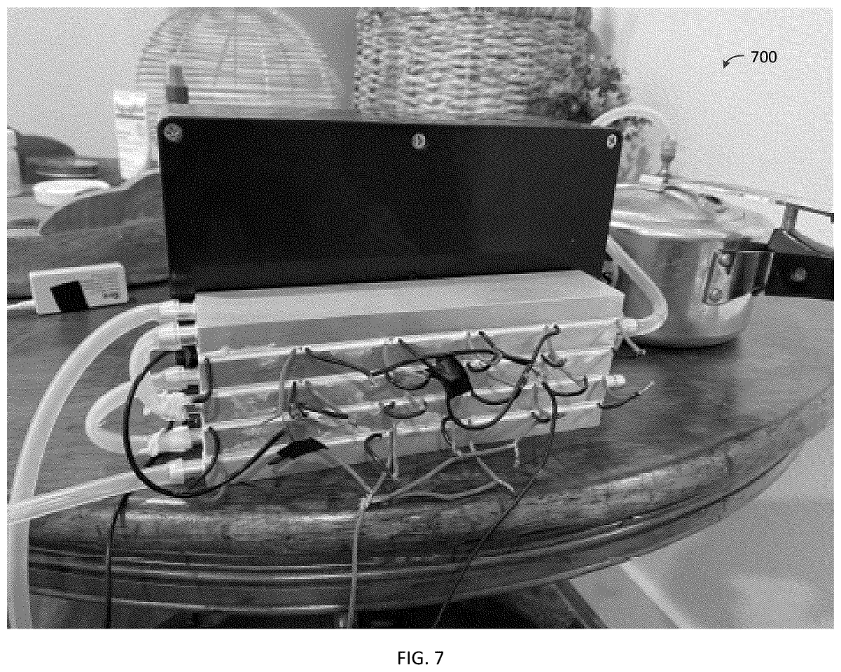

Referring now to FIG. 6, a flowchart of a method 600 in accordance with one embodiment of the present disclosure is shown. A cooling liquid is passed through a first cooling section and a second cooling section in block 602. Steam is condensed into water in a condenser section in block 604. Electricity is generated in block 606 using a first thermoelectric section and a second thermoelectric section, wherein: (1) the first thermoelectric section comprises one or more first thermoelectric modules interposed between the first cooling section and the condenser section, each first thermoelectric module has a cold side in contact with the first cooling section, a hot side in contact with the condenser section, and is configured to generate electricity based on a first temperature difference between the hot side and the cold side of the first thermoelectric module, (2) the second thermoelectric section comprises one or more second thermoelectric modules interposed between the second cooling section and the condenser section, each second thermoelectric module has a cold side in contact with the second cooling section, a hot side in contact with the condenser section, and is configured to generate electricity based on a second temperature difference between the hot side and the cold side of the second thermoelectric module. The electricity is provided to an electrical outlet coupled to the first thermoelectric module(s), or the second thermoelectric module(s), or both the first and second thermoelectric modules in block 608.

In one aspect, the method further includes charging a device or battery, or powering the device connected to the electrical outlet. In another aspect, the method includes pumping water from a water source into the first cooling section, or the second cooling section, or both the first and second cooling sections via a tube, hose or pipe. In another aspect, a tube, hose or pipe connects the first cooling section to the second cooling section. In another aspect, the one or more first thermoelectric modules comprise two or more first thermoelectric modules; the one or more second thermoelectric modules comprise two or more second thermoelectric modules; the electrical outlet comprises a first electrical outlet; a second electrical outlet is coupled to at least one of the two or more first thermoelectric modules or the two or more second thermoelectric modules; and the first electrical outlet is coupled to the two or more first thermoelectric modules and the two or more second thermoelectric modules that are not coupled to the second electrical outlet. In another aspect, the method includes powering a pump connected to the second electrical outlet. In another aspect, all of the first and second thermoelectric modules coupled to the second electrical outlet are connected together in series; all of the first and second thermoelectric modules coupled to the first electrical outlet are configured into one or more groups of thermoelectric modules; all of the first and second thermoelectric modules in each group of thermoelectric modules are connected together in series; and all of the groups of thermoelectric modules are connected together in parallel. In another aspect, the method includes producing the steam by heating a vessel containing water; and transporting the steam from the vessel to the condenser section using a tube, hose or pipe. In another aspect, the method includes collecting the distilled water from the condenser section in a receptacle. In another aspect, the condenser section comprises a first condenser section; one or more expansion units coupled to the first cooling section or the second cooling section, each expansion unit includes: a second condenser section, a third cooling section, a third thermoelectric section comprising one or more third thermoelectric modules interposed between the second condenser section and the first cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and a fourth thermoelectric section comprising one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module; and wherein the electrical outlet is further coupled to the third thermoelectric module(s), or the fourth thermoelectric module(s), or both the third and fourth thermoelectric modules. In another aspect, one or more solar cells or panels are coupled to the electrical outlet. In another aspect, the first cooling section, the second cooling section and the condenser section each comprise: a rectangular shaped body having an inlet and an outlet, wherein the rectangular shaped body is made of a thermally conductive material; and one or more passageways disposed within the rectangular shaped body and connected to the inlet to the outlet. In another aspect, a tube, hose or pipe connects the outlet of the first cooling section to the inlet of the second cooling section, or the outlet of the second cooling section to the inlet of the first cooling section. In another aspect, one or more radiator fins attached to an exterior of the first cooling section, or the second cooling section, or both the first and second cooling sections. In some embodiments, the first cooling section, the condenser section and the second cooling section comprise a primary condenser; and a secondary condenser is coupled to the primary condenser, wherein the secondary condenser comprises an additional condenser section disposed between a third cooling section and a fourth cooling section (see FIG. 8).

The TDM 700 shown in FIG. 7 was tested. The test was conducted with a TDM 700 made up of three cooling chambers and two condensing chambers. This design is twice the size of the standard model TDM, generates double the power and doubles the distillation rate. For data regarding the standard model, it is safe to assume that taking the data presented below and dividing it by two would result in accurate measurements.

### Set Up

2 condenser chambers
3 cooling chambers
4 TEG modules wired in series placed in circuit with water pump
16 TEG modules, 4 modules are wired in series. This is repeated 4 times to create 4 batteries of 4 modules wired in series. Each battery is wired together in parallel, placed in circuit with a charging output USB terminal.
iPhone 11 Pro Max charge starting percentage: 36%
Minimal Ice in cold water reservoir; reservoir is approx. ⅔ to 1 gallon.
1 liter of tap water in the boiler
Tap water has a purity of 429 ppm (parts per million)

### Operation

Boiler lit: 10:45 pm
Distillation begins 10:55
Electricity generation begins 10:55
Distillation and generation begin almost simultaneously
Phone is plugged in and begins charge at 36% at 10:57
Phone is charging at 4.87 volts and 1.13 amps for a total of 5.5031 watts
At 11:02, amperage jumped to 1.43 and is slowly decreasing
At 11:06, amperage has fallen to 1.05 amps
At 11:09 ice is almost completely melted, amperage is now at 0.84 amps
At 11:12 voltage at 4.45 and amperage at 0.83
At 11:12 phone is charged to 43%, charging a total of 7% in 15 minutes
At 11:12 1 cup of water has been distilled in the 15 minutes since distillation began.
At 11:18, cooling water exiting the module is now lukewarm/warm to the touch, amperage has fallen to 0.75 amps
Distilled water has a purity of 11 ppm

If the cooling water is held at a constant temperature that of ice water, then this configuration of the TDM will generate a peak of approx. 7 watts charging power and has the potential to charge a mobile phone from 0% to 50% in one hour and distill one liter of water in the same amount of time.

The TDM can be used for a multitude of tasks, with the main two main functions being water distillation and electricity generation. The TDM can also be used as a compact water heater. If lukewarm/warm water is fed into the cooling chambers input terminal, the condenser chamber will heat it up to a substantial temperature. This process heats the outgoing water, but the electricity generation and distillation rate will only be a fraction of its rated potential.

Now referring to FIG. 8, a photograph of a system 800 in accordance with one embodiment of the present disclosure is shown. The 15 watt TDM 800 is a multi-stage distillation condenser and electric generator. The device leverages the temperature difference needed to re-condense steam in the distillation process to simultaneously power thermoelectric generators. The electricity produced can be harvested out of the integrated 5 volt USB port or 12 volt jack plug output. The two 5 volt USB output terminals are able to produce a max output power of 20 watts (10 watts each).

The TDM 800 has a two-stage function, with the first stage being the primary condenser 802 and the second stage being the secondary condenser 804. The primary condenser 802 is where the electricity is produced. Because of this, it is designed to keep the steam running through the hot blocks as hot as possible. Very little vapor is actually condensed into water in this first stage. The generation condenser consists of four aluminum liquid heat exchanger blocks 806a, 806b, 806c, 806d and ten TEG modules 808 configured in rows of five sandwiched between each block 806. There is one block where hot steam is flowed through and two blocks where cold water is pumped through. The cold water is the coolant needed to facilitate the temperature difference necessary to condense the steam and to run the generators. Four of the TEG modules 808 are wired in series and connected to a 12 volt DC water pump. This pump will be the driver of the coolant fluid. Six of the TEG modules are wired into two different batteries consisting of three TEG modules each. The three batteries are wired in parallel then connected to the two 5 volt USB buck converter. The converters are wired in parallel. Each TEG module in the generation block produces an output power of approximately 1-3 watts depending on operating conditions (i.e. coolant temp and steam supply).

The second stage of the TDM 800 is the secondary condenser 804. The secondary condenser 804 has no TEG modules 808 and consists of just three aluminum heat exchanger blocks 806e, 806f, 806g, one of them is for steam to travel through while the remaining two are for coolant to travel through. The steam block is sandwiched in direct contact with the two coolant blocks. The purpose of the secondary condenser 804 is to completely condense the steam entering the stage back into 100% liquid water before it exits the module 804. The secondary condenser 804 removes almost all of the heat from the steam, which results in cool purified water exiting the module 804. The natural steam pressure produced by the pressure cooker pushes the condensate out of the module.

Under normal operating conditions, the TDM 800 is able to condense approximately 2.5 liters of water per hour and generate a continuous 22 watts of power while running. The colder the coolant temperature the more power is produced. This is because a higher temperature difference increases the efficiency of the generators.

This current configuration can be easily scaled up or down by simply adding more heat exchanger blocks and generators, resulting in the ability to build high or low output units with very minimal alterations to the manufacturing process.

All of the condenser blocks where potable water will pass through have internals made of food grade copper, silicone, stainless steel or other suitable material. This ensures that the produced drinking water has no risk of harmful contaminates carrying over during the distillation process.

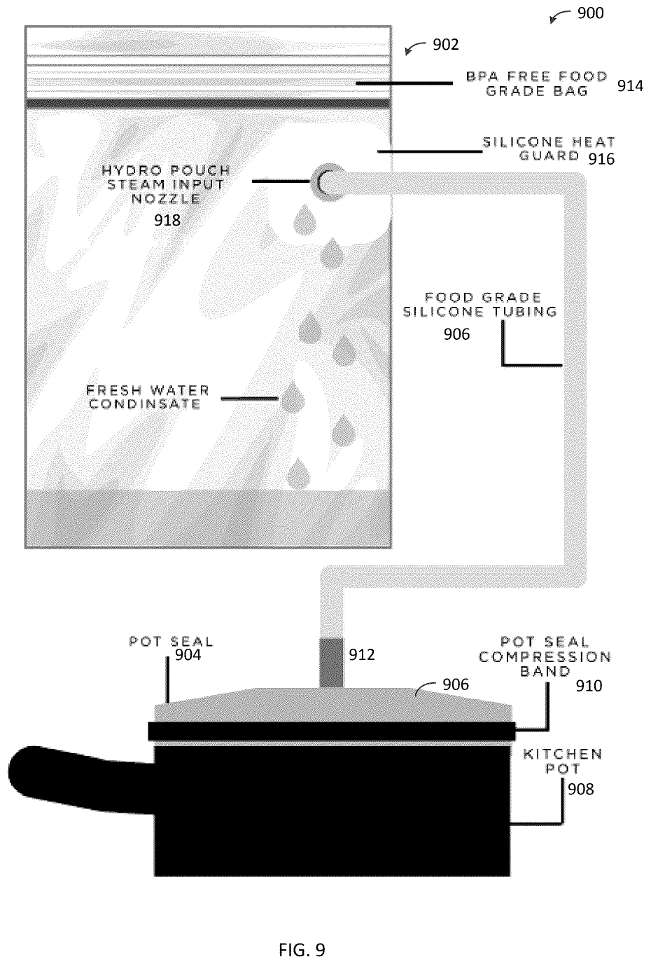

Referring now to FIG. 9, a diagram of a hydro pouch system 900 in accordance with one embodiment of the present disclosure is shown. The hydro pouch system 900 is an extremely portable and low weight distillation condenser unit meant to serve the purpose of desalinating and sterilizing water for drinking. The hydro pouch system 900 utilizes a BPA free food grade bag 902 that acts as the condenser. The condenser bag 902 is connected to a custom pot seal technology 904 via food grade silicone tubing 906. Other suitable materials can be used. The pot seal 904 is compatible with almost any common kitchen pot and serves the purpose of funneling steam from the pot to the condenser bag. The pot seal 904 is a tool that allows the user to turn almost any common kitchen pot into a functional boiler for a distiller. The pot seal 904 includes a silicone cover 906 that is stretched over the top of the pot 908 and secured with a compression band 910. The compression band 910 is a silicone band that keeps the pot seal 904 from slipping off the pot 908. Other suitable materials can be used. An airtight nozzle 912 in the middle of the silicone cover 906 allows steam to escape. This is what the food grade silicone tubing 906 will be connected to.

The condenser bag 902 is an attachment to the pot seal 904 which allows steam that exits the pot seal to condense as fresh water. The main purpose of this is to desalinate and sterilize water. It will also remove sediment and most other impurities. The condenser bag 902 itself is a BPA free food grade silicone bag 914, a silicone patch or heat patch 916 to act as a heat buffer, and an inlet nozzle 918 for the steam to enter. An additional item needed is a length of food grade silicone tube 906. The silicone heat buffer or guard 916 is secured to the inside of the bag 914 on the opposite side of the inlet nozzle 918. This prevents the bag 914 from being damaged from direct steam contact.

During operation, the bag 914 is floated in cool, moving water (such as a creek, river, lake or ocean) which creates an efficient heat sink. This temperature difference condenses the entering steam back into liquid form. Though using a bucket or other non-moving confined source of cooling water will work, it needs to be constantly tended to prevent overheating. Tending to it would mean pouring water over the bag 914 and moving it around as if it was in a natural body of moving water.

The hydro pouch 900 is able to remove almost all impurities and contaminants, including salt, from any given source of water. This is done through the process of distillation, where water is boiled and turned into steam then condensed and collected as fresh, purified drinking water. The hydro pouch 900 utilizes a common kitchen pot as its boiling apparatus with its pot seal and condenser bag to create an extremely portable and efficient means of water desalination and purification. The unit will function with any heat source that can boil water, including a gas stove, wood stove, camp fire or solar cooker. Under normal operation, the hydro pouch 900 is able to purify over 1 liter of water per hour.

It is understood that particular embodiments described herein are shown by way of illustration and not as limitations of the invention. The principal features of this invention can be employed in various embodiments without departing from the scope of the invention. Those skilled in the art will recognize or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited features, elements, components, groups, integers, and/or steps, but do not exclude the presence of other unstated features, elements, components, groups, integers and/or steps. In embodiments of any of the compositions and methods provided herein, “comprising” may be replaced with “consisting essentially of” or “consisting of”. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only. As used herein, the phrase “consisting essentially of” requires the specified features, elements, components, groups, integers, and/or steps, but do not exclude the presence of other unstated features, elements, components, groups, integers and/or steps as well as those that do not materially affect the basic and novel characteristic(s) and/or function of the claimed invention.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. A distillation and electricity generation system, comprising:
a first cooling section configured to receive a cooling liquid;
a condenser section configured to condense steam into distilled water;
a second cooling section configured to receive the cooling liquid;
a first thermoelectric section comprising one or more first thermoelectric modules interposed between the first cooling section and the condenser section, wherein each first thermoelectric module has a cold side in contact with the first cooling section, a hot side in contact with the condenser section, and is configured to generate electricity based on a first temperature difference between the hot side and the cold side of the first thermoelectric module;
a second thermoelectric section comprising one or more second thermoelectric modules interposed between the second cooling section and the condenser section, wherein each second thermoelectric module has a cold side in contact with the second cooling section, a hot side in contact with the condenser section, and is configured to generate electricity based on a second temperature difference between the hot side and the cold side of the second thermoelectric module; and
an electrical outlet coupled to the first thermoelectric module(s), or the second thermoelectric module(s), or both the first and second thermoelectric modules.

2. The system of claim 1, wherein:
the one or more first thermoelectric modules comprise two or more first thermoelectric modules;
the one or more second thermoelectric modules comprise two or more second thermoelectric modules;
the electrical outlet comprises a first electrical outlet;
a second electrical outlet is coupled to at least one of the two or more first thermoelectric modules or the two or more second thermoelectric modules; and
the first electrical outlet is coupled to the two or more first thermoelectric modules and the two or more second thermoelectric modules that are not coupled to the second electrical outlet.

3. The system of claim 2, wherein:
the first electrical outlet is configured to charge a device or battery, or to power the device; and
the second electrical outlet is configured to power a pump.

4. The system of claim 3, wherein:
all of the first and second thermoelectric modules coupled to the second electrical outlet are connected together in series;
all of the first and second thermoelectric modules coupled to the first electrical outlet are configured into one or more groups of thermoelectric modules;
all of the first and second thermoelectric modules in each group of thermoelectric modules are connected together in series; and
all of the groups of thermoelectric modules are connected together in parallel.

5. The system of claim 3, wherein:
the pump is electrically connected to the second electrical output; and
the pump is configured to pump water from a water source into the first cooling section, or the second cooling section, or both the first and second cooling sections via a tube, hose or pipe.

6. The system of claim 1, further comprising a vessel configured to receive heat from a heat source, create steam from water contained within the vessel using the heat, and direct the steam into the condenser section via a tube, hose or pipe.

7. The system of claim 1, further comprising a receptacle configured to receive the distilled water from the condenser section.

8. The system of claim 1, further comprising a tube, hose or pipe connecting the first cooling section to the second cooling section.

9. The system of claim 1, further comprising:
the condenser section comprises a first condenser section;
one or more expansion units coupled to the first cooling section or the second cooling section, each expansion unit comprising:
a second condenser section,
a third cooling section,
a third thermoelectric section comprising one or more third thermoelectric modules interposed between the second condenser section and the first cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and
a fourth thermoelectric section comprising one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module; and
wherein the electrical outlet is further coupled to the third thermoelectric module(s), or the fourth thermoelectric module(s), or both the third and fourth thermoelectric modules.

10. The system of claim 1, further comprising one or more solar cells or panels coupled to the electrical outlet.

11. The system of claim 1, wherein the first cooling section, the second cooling section and the condenser section each comprise:
a rectangular shaped body having an inlet and an outlet, wherein the rectangular shaped body is made of a thermally conductive material; and
one or more passageways disposed within the rectangular shaped body and connected to the inlet to the outlet.

12. The system of claim 11, further comprising a tube, hose or pipe connecting the outlet of the first cooling section to the inlet of the second cooling section, or the outlet of the second cooling section to the inlet of the first cooling section.

13. The system of claim 1, further comprising one or more radiator fins attached to an exterior of the first cooling section, or the second cooling section, or both the first and second cooling sections.

14. The system of claim 1, wherein:
the first cooling section, the condenser section and the second cooling section comprise a primary condenser; and
a secondary condenser is coupled to the primary condenser, wherein the secondary condenser comprises an additional condenser section disposed between a third cooling section and a fourth cooling section.

15. A distillation and electricity generation system, comprising:
a first cooling section configured to receive a cooling liquid;
a condenser section configured to condense steam into distilled water;
a second cooling section configured to receive the cooling liquid;
wherein the first cooling section, the second cooling section and the condenser section each comprise:
a rectangular shaped body having an inlet and an outlet, wherein the rectangular shaped body is made of a thermally conductive material, and
one or more passageways disposed within the rectangular shaped body and connected to the inlet to the outlet;
a first thermoelectric section comprising two or more first thermoelectric modules interposed between the first cooling section and the condenser section, wherein each first thermoelectric module has a cold side in contact with the first cooling section, a hot side in contact with the condenser section, and is configured to generate electricity based on a first temperature difference between the hot side and the cold side of the first thermoelectric module;
a second thermoelectric section comprising two or more second thermoelectric modules interposed between the second cooling section and the condenser section, wherein each second thermoelectric module has a cold side in contact with the second cooling section, a hot side in contact with the condenser section, and is configured to generate electricity based on a second temperature difference between the hot side and the cold side of the second thermoelectric module; and
a first electrical outlet;
a second electrical outlet coupled to at least one of the two or more first thermoelectric modules or the two or more second thermoelectric modules;
wherein the first electrical outlet is coupled to the two or more first thermoelectric modules and the two or more second thermoelectric modules that are not coupled to the second electrical coupled.

16. The system of claim 15, wherein:
the first electrical outlet is configured to charge a device or battery, or to power the device; and
the second electrical outlet is configured to power a pump.

17. The system of claim 16, wherein:
all of the first and second thermoelectric modules coupled to the second electrical outlet are connected together in series;
all of the first and second thermoelectric modules coupled to the first electrical outlet are configured into one or more groups of thermoelectric modules;
all of the first and second thermoelectric modules in each group of thermoelectric modules are connected together in series; and
all of the groups of thermoelectric modules are connected together in parallel.

18. The system of claim 16, wherein:
the pump is electrically connected to the second electrical output; and
the pump is configured to pump water from a water source into the first cooling section, or the second cooling section, or both the first and second cooling sections via a tube, hose or pipe.

19. The system of claim 15, further comprising a vessel configured to receive heat from a heat source, create steam from water contained within the vessel using the heat, and direct the steam into the condenser section via a tube, hose or pipe.

20. The system of claim 15, further comprising a receptacle configured to receive the distilled water from the condenser section.

21. The system of claim 15, further comprising a tube, hose or pipe connecting the outlet of the first cooling section to the inlet of the second cooling section, or the outlet of the second cooling section to the inlet of the first cooling section.

22. The system of claim 15, further comprising:
the condenser section comprises a first condenser section;
one or more expansion units coupled to the first cooling section or the second cooling section, each expansion unit comprising:
a second condenser section,
a third cooling section,
a third thermoelectric section comprising one or more third thermoelectric modules interposed between the second condenser section and the first cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and
a fourth thermoelectric section comprising one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module; and
wherein the electrical outlet is further coupled to the third thermoelectric module(s), or the fourth thermoelectric module(s), or both the third and fourth thermoelectric modules.

23. The system of claim 15, further comprising one or more solar cells or panels coupled to the electrical outlet.

24. The system of claim 15, further comprising one or more radiator fins attached to an exterior of the first cooling section, or the second cooling section, or both the first and second cooling sections.

25. The system of claim 15, wherein:
the first cooling section, the condenser section and the second cooling section comprise a primary condenser; and
a secondary condenser is coupled to the primary condenser, wherein the secondary condenser comprises an additional condenser section disposed between a third cooling section and a fourth cooling section.

26. A method comprising:
passing a cooling liquid through a first cooling section and a second cooling section;
condensing steam into water in a condenser section;
generating electricity using a first thermoelectric section and a second thermoelectric section, wherein: (1) the first thermoelectric section comprises one or more first thermoelectric modules interposed between the first cooling section and the condenser section, each first thermoelectric module has a cold side in contact with the first cooling section, a hot side in contact with the condenser section, and is configured to generate electricity based on a first temperature difference between the hot side and the cold side of the first thermoelectric module, (2) the second thermoelectric section comprises one or more second thermoelectric modules interposed between the second cooling section and the condenser section, each second thermoelectric module has a cold side in contact with the second cooling section, a hot side in contact with the condenser section, and is configured to generate electricity based on a second temperature difference between the hot side and the cold side of the second thermoelectric module; and
providing the electricity to an electrical outlet coupled to the first thermoelectric module(s), or the second thermoelectric module(s), or both the first and second thermoelectric modules.

27. The method of claim 26, further comprising charging a device or battery, or powering the device connected to the electrical outlet.

28. The method of claim 26, further comprising pumping water from a water source into the first cooling section, or the second cooling section, or both the first and second cooling sections via a tube, hose or pipe.

29. The method of claim 26, further comprising a tube, hose or pipe connecting the first cooling section to the second cooling section.

30. The method of claim 26, wherein:
the one or more first thermoelectric modules comprise two or more first thermoelectric modules;
the one or more second thermoelectric modules comprise two or more second thermoelectric modules;
the electrical outlet comprises a first electrical outlet;
a second electrical outlet is coupled to at least one of the two or more first thermoelectric modules or the two or more second thermoelectric modules; and
the first electrical outlet is coupled to the two or more first thermoelectric modules and the two or more second thermoelectric modules that are not coupled to the second electrical outlet.

31. The method of claim 30, further comprising powering a pump connected to the second electrical outlet.

32. The method of claim 30, wherein:
all of the first and second thermoelectric modules coupled to the second electrical outlet are connected together in series;
all of the first and second thermoelectric modules coupled to the first electrical outlet are configured into one or more groups of thermoelectric modules;
all of the first and second thermoelectric modules in each group of thermoelectric modules are connected together in series; and
all of the groups of thermoelectric modules are connected together in parallel.

33. The method of claim 26, further comprising:
producing the steam by heating a vessel containing water; and
transporting the steam from the vessel to the condenser section using a tube, hose or pipe.

34. The method of claim 26, further comprising collecting the distilled water from the condenser section in a receptacle.

35. The method of claim 26, wherein:
the condenser section comprises a first condenser section;
one or more expansion units coupled to the first cooling section or the second cooling section, each expansion unit comprising:
a second condenser section,
a third cooling section,
a third thermoelectric section comprising one or more third thermoelectric modules interposed between the second condenser section and the cooling section or the second cooling section, wherein each third thermoelectric module has a cold side in contact with the first cooling section or the second cooling section, a hot side in contact with the second condenser section, and is configured to generate electricity based on a third temperature difference between the hot side and the cold side of the third thermoelectric module, and
a fourth thermoelectric section comprising one or more fourth thermoelectric modules interposed between the second condenser section and the third cooling section, wherein each fourth thermoelectric module has a cold side in contact with the third cooling section, a hot side in contact with the second condenser section, and is configured to generate electricity based on a fourth temperature difference between the hot side and the cold side of the fourth thermoelectric module; and
wherein the electrical outlet is further coupled to the third thermoelectric module(s), or the fourth thermoelectric module(s), or both the third and fourth thermoelectric modules.

36. The method of claim 26, further comprising one or more solar cells or panels coupled to the electrical outlet.

37. The method of claim 26, wherein the first cooling section, the second cooling section and the condenser section each comprise:
a rectangular shaped body having an inlet and an outlet, wherein the rectangular shaped body is made of a thermally conductive material; and
one or more passageways disposed within the rectangular shaped body and connected to the inlet to the outlet.

38. The method of claim 37, further comprising a tube, hose or pipe connecting the outlet of the first cooling section to the inlet of the second cooling section, or the outlet of the second cooling section to the inlet of the first cooling section.

39. The method of claim 26, further comprising one or more radiator fins attached to an exterior of the first cooling section, or the second cooling section, or both the first and second cooling sections.

40. The method of claim 26, wherein:
the first cooling section, the condenser section and the second cooling section comprise a primary condenser; and
a secondary condenser is coupled to the primary condenser, wherein the secondary condenser comprises an additional condenser section disposed between a third cooling section and a fourth cooling section.
